(19) United States
(12) Patent Application Publication
(10) Pub. No.: US 2024/0360754 A1
(43) Pub. Date: Oct. 31, 2024

(54) BLAST HOLE MEASUREMENT AND LOGGING

(71) Applicant: Four Flags Pty Ltd, Westminster (AU)

(72) Inventor: Christopher Royce Loveland, Westminster (AU)

(73) Assignee: Four Flags Pty Ltd, Westminster (AU)

(21) Appl. No.: 18/765,209

(22) Filed: Jul. 5, 2024

Related U.S. Application Data
(63) Continuation of application No. 17/266,529, filed on Feb. 5, 2021.

(30) Foreign Application Priority Data
Aug. 8, 2018 (AU) 2018902879
May 21, 2019 (AU) 2019901731

(51) Int. Cl. E21B 47/04; E21B 7/00; E21B 47/003; E21B 47/135; E21F 17/18; F42D 1/08; F42D 3/04; G01B 11/22; G01S 17/10; G01S 17/89

(52) U.S. Cl. CPC E21B 47/04; E21B 7/007; E21B 47/003; G01S 17/10; G01S 17/89; E21B 47/135; E21F 17/18; F42D 1/08; F42D 3/04; G01B 11/22

(57) ABSTRACT

A blast hole measurement and logging apparatus, which generally comprises a housing configured to operatively house a solid-state LiDAR sensor array configured to transmit and steer pulses of light into a blast hole by shifting a phase of the pulses through the array to compile volumetric data of the sensor's field-of-view. Also included is a processor configured to receive the volumetric data from the LiDAR sensor, the volumetric data indicative of an internal volume of the blast hole which is useable in calculating an explosive charge according to a blast plan, the processor configured to store and/or transmit the volumetric data.

### CROSS-REFERENCE TO RELATED APPLICATIONS

This application is a continuation of application Ser. No. 17/266,529 filed Feb. 5, 2021, which is a national phase entry under 35 U.S.C. § 371 of International Patent Application PCT/AU2019/050830, filed Aug. 8, 2019, designating the United States of America and published as International Patent Publication WO 2020/028951 A1 on Feb. 13, 2020, which claims the benefit under Article 8 of the Patent Cooperation Treaty to Australian Patent Application Serial No. 2018902879, filed Aug. 8, 2018, and Australian Patent Application Serial No. 2019901731, filed May 21, 2019.

### TECHNICAL FIELD

The present disclosure relates to the field of drilling and blasting, in general, and more specifically to apparatus and associated system for blast hole measurement and logging, and a method for measuring and logging blast holes.

### BACKGROUND

The following discussion of the background art is intended to facilitate an understanding of the present disclosure only. The discussion is not an acknowledgement or admission that any of the material referred to is or was part of the common general knowledge as at the priority date of the application.

Drilling and blasting is the controlled use of explosives and other methods such as gas pressure blasting or pyrotechnics to break rock for excavation. It is practiced most often in mining, with the most commonly used explosives being ANFO based blends (ammonium nitrate/fuel oil). Drill rigs drill a plurality of blast holes into a bench or ore body according to a carefully designed blasting plan, whereafter the holes are charged or filled with a predetermined amount of explosives and the ore body is blasted.

The proper loading of blast holes is typically important to successful blasting practices, as the location and explosive loading determine the blast pattern and characteristics of the material after blasting, e.g., fragmentation, location, etc. A successful blast is directly dependent on accurately loading or charging every blast hole with the correct type and amount of explosives. Therefore, the depth of a blast hole must be known before loading or charging with explosives.

Conventionally, a technique known as “dipping” is used to determine the depth of a blast hole prior to charging explosives into the blast hole to ensure proper loading according to the blasting plan. Dipping generally involves a person manually lowering a weighted rope or line down the blast hole to check the depth of the drilled hole. This process is a time-consuming, labor-intensive and tedious process. In addition, there are often large variations in accuracy depending on the person carrying out the dipping process. There is also the problem that, because dipping is a manual process, it may not be diligently performed on every hole due to time constraints, laziness, etc. If every hole is not dipped so that the correct amount of explosives is charged into each hole, unforeseen variations in the blasting pattern could occur, potentially leading to under-recovery of ore or resulting in less satisfactory grades of ore after a blast.

Under conventional dipping practices, a mine site employee drives to a set of drilled blast holes that require their depth to be measured prior to charging. The average drill pattern of blast holes can vary substantially according to requirements, with examples including 400 blast holes spaced 7 meters apart. This is quite a significant walk during manual dipping when individual mines drill in excess of 200,000 blast holes per year. Blast holes are typically 11.5 meters deep and vary in diameter from 152 mm to 251 mm (specifications typical of iron ore mines in Western Australia, with other blast holes globally ranging from 85 mm to 400 mm in diameter).

A person involved in dipping is typically given an A3 paper map or tablet of drilled blast holes with assigned hole numbers and required design depths. The person then takes out their dipping tape (such as a flexible fiberglass tape on a wheel) to which they attach a weight and proceeds to lower the weight down each hole. The person then looks at the ‘dipped depth’ and writes it either on a map or on a tablet containing the blast hole data. This data is then taken back to the office where another person re-enters the data into a spreadsheet. Once this data is captured, it is compared against the design drilled depth or the blast plan and is used to alter the quantity of explosive that goes into each hole.

As described, due to the amount of work involved, often under severe conditions (high heat, humidity, etc.) and other frustrating factors (time consuming and frustrating field processes, including hard to read maps or screens, wind and rain) in which this data is usually collected, it is sometimes just ‘made up’ from the comfort of an air-conditioned vehicle, i.e., the person enters fictitious data against each blast hole. This leads to a significant amount of wasted explosive or insufficient blasting, which is even more costly. The whole process of dipping is archaic and has numerous human error elements, which are typically compensated for by using more explosive, which comes at a significant cost to the mine owner.

The present disclosure was conceived with these shortcomings in mind in an attempt to propose possible solutions, at least in part, to the known shortcomings in the art of conventional blast hole dipping practices.

### BRIEF SUMMARY

The skilled addressee will appreciate that reference herein to LiDAR (light detection and ranging) generally refers to technology using light pulses emitted to determine a particular distance based on nm or flight time and speed of light. LiDAR is an optical method for measuring distance and speed that is similar to radar, except that laser pulses are used instead of radio waves. In this specification, reference to LiDAR it to be interpreted as broadly referring to any radiation in the electromagnetic spectrum for use in measuring distance based on speed of wave and run or flight time.

The skilled addressee will further appreciate that a global navigation satellite system (GNSS) generally comprises a satellite navigation system with global coverage, e.g., as of December 2016, the United States' Global Positioning System (GPS), Russia's GLONASS and the European Union's Galileo are global operational GNSSs, but other types of GNSS systems are possible and within the scope of the present disclosure.

According to a first aspect of the present disclosure there is provided a blast hole measurement and logging apparatus comprising:
a housing configured to operatively house:
a solid-state LiDAR sensor array configured to transmit and steer pulses of light into a blast hole by shifting a phase of the pulses through the array to compile volumetric data of the sensor's field-of-view; and
a processor configured to receive the volumetric data from the LiDAR sensor and to calculate distance data based on the volumetric data for storage and/or transmission.

In one example, the LiDAR sensor array includes an optical phased array configured to transmit and steer pulses of light.

Alternatively, the LiDAR sensor array includes a microelectromechanical systems (MEMS) mirror array configured to transmit and steer pulses of light, e.g., bistable deformable mirror device (DMD) pixel architecture, or the like.

Alternatively, the LiDAR sensor array includes a flash LiDAR arrangement having a three-dimensional focal plane array configured to transmit and steer pulses of light.

In one example, the apparatus includes a GNSS module configured to provide geographic positional data to within 1-meter accuracy or less for each instance when the volumetric data is compiled, the processor being configured to collate the geographic positional date from the GNSS module with the distance data for storage and/or transmission.

Typically, the apparatus includes a transmitter whereby the processor is able to transmit the collated distance and geographic positional data to a remote computer system, which is configured to log the data.

Typically, the apparatus includes a display whereby the geographic positional, volumetric and/or distance data is displayable to a user.

Typically, the display comprises an electronic ink (e-ink) display having high visibility and contrast, a wide viewing angle and low power requirements.

Typically, the housing comprises a ruggedized housing to protect housed components against shock, vibration and/or the ingress of dust and fluid.

Typically, the housing is shaped and dimensioned to be easily man-portable.

Typically, the processor is configured to calculate distance data based on the volumetric data via point cloud algorithms configured to determine a maximum depth and/or maximum average depth of the blast hole.

Typically, the processor is configured to calculate the maximum average depth of the blast hole via factoring for average depth against a width of the blast hole following analysis of the volumetric data.

Typically, the processor is configured to calculate the maximum depth of the blast hole via furthest measured distance following analysis of the volumetric data.

Typically, the volumetric data is indicative of a lip, edge or start of the blast hole to allow the distance data to be calculated irrespective of a position of the LiDAR sensor above the blast hole.

Typically, the processor includes a non-transitory memory wherein the geographic positional, volumetric and/or distance data is storable.

Typically, the apparatus includes energizing means configured to provide electrical energy to the LiDAR sensor, GNSS module and processor.

In one example, the apparatus is automated and includes self-propelled locomotion to move between blast holes.

Typically, the self-propelled locomotion comprises an aerial drone configuration.

In one example, the apparatus is mounted to an explosive loading or charging truck (automated or human operated) operatively moving between blast holes for charging the blast holes with explosives.

In one example, the charging truck includes the GNSS module configured to provide geographic positional data to the processor.

According to a second aspect of the present disclosure there is provided a blast hole measurement and logging apparatus comprising:
a housing configured to operatively house:
a solid-state LiDAR sensor array configured to transmit and steer pulses of light into a blast hole by shifting a phase of the pulses through the array to compile volumetric data of the sensor's field-of-view;
a GNSS module configured to provide geographic positional data to within 1-meter accuracy or less for an instance when the volumetric data is compiled; and
a processor configured to receive the geographic positional and volumetric data from the GNSS module and LiDAR sensor, respectively, to calculate distance data based on the volumetric data, and to collate the distance data with the geographic positional data for storage and/or transmission.

In one example, the LiDAR sensor array includes an optical phased array configured to transmit and steer pulses of light.

Alternatively, the LiDAR sensor array includes a microelectromechanical systems (MEMS) minor array configured to transmit and steer pulses of light. e.g., bistable deformable mirror device (DMD) pixel architecture, or the like.

Alternatively, the LiDAR sensor array includes a flash LiDAR arrangement having a three-dimensional focal plane array configured to transmit and steer pulses of light.

Typically, the apparatus includes a transmitter whereby the processor is able to transmit the collated distance and geographic positional data to a remote computer system, which is configured to log the data.

Typically, the apparatus includes a display whereby the geographic positional, volumetric and/or distance data is displayable to a user.

Typically, the display comprises an electronic ink (e-ink) display having high visibility and contrast, a wide viewing angle and low power requirements.

Typically, the housing comprises a ruggedized housing to protect housed components against shock, vibration and/or the ingress of dust and fluid.

Typically, the housing is shaped and dimensioned to be easily man-portable.

Typically, the processor is configured to calculate distance data based on the volumetric data via point cloud algorithms configured to determine a maximum depth and/or maximum average depth of the blast hole.

Typically, the processor is configured to calculate the maximum average depth of the blast hole via factoring for average depth against a width of the blast hole following analysis of the volumetric data.

Typically, the processor is configured to calculate the maximum depth of the blast hole via furthest measured distance following analysis of the volumetric data.

Typically, the volumetric data is indicative of a lip, edge or start of the blast hole to allow the distance data to be calculated irrespective of a position of the LiDAR sensor above the blast hole.

Typically, the processor includes a non-transitory memory wherein the geographic positional, volumetric and/or distance data is storable.

Typically, the apparatus includes energizing means configured to provide electrical energy to the LiDAR sensor, GNSS module and processor.

In one example, the apparatus is automated and includes self-propelled locomotion to move between blast holes.

Typically, the self-propelled locomotion comprises an aerial drone configuration.

In one example, the apparatus is mounted to an explosive loading or charging truck (automated or human operated) operatively moving between blast holes for charging the blast holes with explosives.

According to a third aspect of the present disclosure there is provided a blast hole measurement and logging system comprising:
at least one blast hole measurement and logging apparatus in accordance with the first or second aspects of the present disclosure; and
a remote computer system that is configured to receive the transmitted collated distance and geographic positional data and to log the data as part of a blast hole plan.

According to a fourth aspect of the present disclosure there is provided a blast hole measurement and logging system comprising:
at least one blast hole measurement and logging apparatus having a housing configured to operatively house a solid-state LiDAR sensor array configured to transmit and steer pulses of light into a blast hole by shifting a phase of the pulses through the array to compile volumetric data of the sensor's field-of-view; a GNSS module configured to provide geographic positional data to within 1-meter accuracy or less for an instance when the volumetric data is compiled; and a processor configured to receive the geographic positional and volumetric data from the GNSS module and LiDAR sensor, respectively, to calculate distance data based on the volumetric data, and to collate the distance data with the geographic positional data; and a transmitter whereby the processor is able to transmit the collated distance and geographic positional data; and
a remote computer system that is configured to receive the transmitted collated distance and geographic positional data and to log the data as part of a blast hole plan.

Typically, the system includes a plurality of blast hole measurements and logging apparatuses.

Typically, the apparatus is automated and includes self-propelled locomotion to move between blast holes.

Typically, the self-propelled locomotion comprises an aerial drone configuration.

In one example, the LiDAR sensor array includes an optical phased array configured to transmit and steer pulses of light.

Alternatively, the LiDAR sensor array includes a microelectromechanical systems (MEMS) mirror array configured to transmit and steer pulses of light, e.g., bistable deformable mirror device (DMD) pixel architecture, or the like.

Alternatively, the LiDAR sensor array includes a flash LiDAR arrangement having a three-dimensional focal plane array configured to transmit and steer pulses of light.

Typically, the housing comprises a ruggedized housing to protect housed components against shock, vibration and/or the ingress of dust and fluid.

Typically, the processor is configured to calculate distance data based on the volumetric data via point cloud algorithms configured to determine a maximum depth and/or maximum average depth of the blast hole.

Typically, the processor is configured to calculate the maximum average depth of the blast hole via factoring for average depth against a width of the blast hole following analysis of the volumetric data.

Typically, the processor is configured to calculate the maximum depth of the blast hole via furthest measured distance following analysis of the volumetric data.

Typically, the volumetric data is indicative of a lip, edge or start of the blast hole to allow the distance data to be calculated irrespective of a position of the LiDAR sensor above the blast hole.

Typically, the processor includes a non-transitory memory wherein the geographic positional, volumetric and/or distance data is storable.

Typically, the apparatus includes energizing means configured to provide electrical energy to the LiDAR sensor, GNSS module and processor.

In one example, the apparatus is mounted to an explosive loading or charging truck (automated or human operated) operatively moving between blast holes for charging the blast holes with explosives.

According to a fifth aspect of the present disclosure there is provided a method for blast hole measurement and logging comprising:
providing blast hole measurement and logging apparatus in accordance with the first or second aspects of the present disclosure;
measuring and compiling volumetric data for a plurality of blast holes, the data subsequently collated with respective geographic positional data for each blast hole; and
logging the distance and geographic positional data as part of a blast hole plan.

Typically, the method includes the step of calculating the distance data based on the volumetric data via point cloud algorithms configured to determine a maximum depth and/or maximum average depth of the blast hole.

Typically, the maximum average depth of the blast hole is calculated via factoring for average depth against a width of the blast hole following analysis of the volumetric data.

Typically, the maximum depth of the blast hole is calculated via analysis of the volumetric data to determine furthest measured distance.

In one example, the step of providing the apparatus comprises providing the apparatus, which is automated, and includes self-propelled locomotion to move between blast holes.

Typically, the self-propelled locomotion comprises an aerial drone configuration.

### BRIEF DESCRIPTION OF THE DRAWINGS

The description will be made with reference to the accompanying drawings wherein:

FIG. 1 is a diagrammatic top-view representation of a conventional blast hole plan, showing a plurality of blast holes drilled in a bench or ore body;

FIG. 2 is a diagrammatic representation of a blast hole measurement and logging apparatus in accordance with an aspect of the present disclosure;

FIG. 3 is a diagrammatic representation of a blast hole measurement and logging system in accordance with an aspect of the present disclosure; and

FIG. 4 is a diagrammatic representation of representative method steps of a method for blast hole measurement and logging in accordance with an aspect of the present disclosure.

### DETAILED DESCRIPTION

Further features of the present disclosure are more fully described in the following description of several non-limiting embodiments thereof. This description is included solely for the purposes of exemplifying the present disclosure to the skilled addressee. It should not be understood as a restriction on the broad summary, disclosure or description of the present disclosure as set out above. In the figures, incorporated to illustrate features of the example embodiment or embodiments, like reference numerals are used to identify like parts throughout.

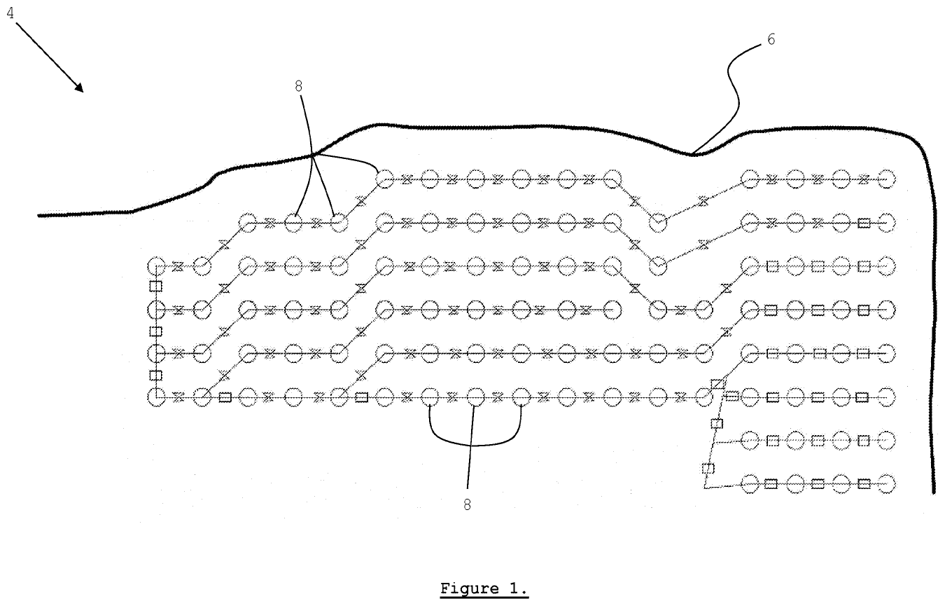

With reference now to FIG. 1 of the accompanying drawings, there is shown an example of a conventional blast hole plan 4, showing a plurality of blast holes 8 drilled in a bench or ore body 6, as is known in the art. The blast hole plan 4 generally indicates a location of required blast holes 8, which is drilled by means of a drill rig, or the like, up to a specified depth to ensure adequate and desired fragmentation of the ore body 6 during blasting. As is known in the art, drilling of blast holes is often an inexact operation, leading to blast holes that are deeper (or shallower) than design requirements, necessitating changes to the type and/or quantity of explosives to be loaded in the blast holes prior to blasting.

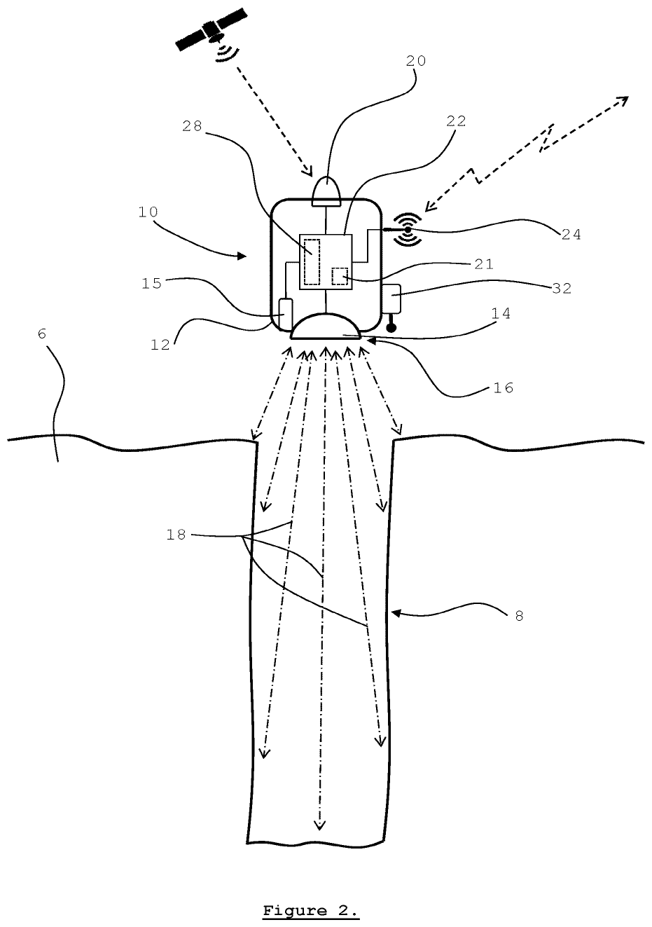

FIG. 2 shows an example of a blast hole measurement and apparatus 10, in accordance with as aspect of the present disclosure. Apparatus 10 generally comprises a housing 12, which is configured to operatively house certain components, described in more detail below. In one example, the housing 12 is ruggedized to protect housed components against shock, vibration and/or the ingress of dust and fluid, as relevant to harsh environments such as mine sites. The housing 12 may be shaped and dimensioned to be easily man-portable where apparatus 10 is operated by a person, or it may be part of an automated arrangement, as described in more detail below.

Apparatus 10 includes a solid-state LiDAR sensor 14 having an optical phased array 16, which is configured to transmit and steer pulses of light 18 into a blast hole 8 by shifting a phase of the pulses of light 18 through the optical phased array 16 to compile volumetric data of the sensor's field-of-view. Apparatus 10 also include a GNSS module 20 configured to provide geographic positional data to within 1-meter accuracy or less for an instance when the volumetric data is compiled, e.g., when the LiDAR sensor 14 scans or measures a blast hole 8.

Apparatus 10 further includes a processor 22, which is configured to receive the geographic positional and volumetric data from the GNSS module 20 and LiDAR sensor 14, respectively, and to calculate distance data based on the volumetric data. The skilled addressee will appreciate that the processor 22 may comprise any suitable microprocessor or microcontroller able to execute an instruction set to perform the required functions.

The processor 22 may be configured to calculate the distance data based on the volumetric data via point cloud algorithms configured to determine a maximum depth and/or maximum average depth of the blast hole 8, as is known in the field of data analysis. In once example, the processor 22 is configured to calculate the maximum average depth of the blast hole 8 via factoring for average depth against a width of the blast hole 8 following analysis of the volumetric data.

For example, for a 12 m designed blast hole, the pulses of light 18 steered into and across an interior of the blast hole 8 via the optical phased array 16 may detect, for argument's sake, 50 data points to compile the volumetric data. Of such 50 data point, 10 might be measurements of between 2 meters (m) and 9 m, which the processor recognizes as wall measurements. Thirty-five (35) of the data points may lie in the range between 11.8 m and 12.4 m, which averages to 12.3 m. The processor then calculates maximum average depth of the blast hole as 12.3 m.

Alternatively, or additionally, the processor 22 may be configured to calculate the maximum depth of the blast hole via furthest measured distance following analysis of the volumetric data. Returning to the above example, where 35 of the data points may lie in the range between 11.8 m and 12.4 in. the processor calculates the maximum depth of the blast hole at 12.4 m.

The skilled addressee will appreciate that various different algorithms are possible for calculating blast hole depth, depending on volumetric data, sensor characteristics, operating environment, and/or the like. As a result, variations on distance data calculation algorithms are envisaged and skilled artisans to employ such variations are expected.

In a further example, the volumetric data is indicative of a lip, edge or start of the blast hole 8, allowing the distance data to be calculated irrespective of a position of the LiDAR sensor 14 above the blast hole. For example, the LiDAR sensor 14 can sense where the blast hole 8 begins, as well as its depth, to allow the processor 22 to calculate the distance data irrespective of a height or even an angle of the LiDAR sensor 14 relative to the blast hole 8. In most examples, however, the field-of-view of the LiDAR sensor 14 needs to be directed downwards into the blast hole 8 to accurately sense its depth.

The processor 22 is further configured to collate the distance data with the geographic positional data from the GNSS module 20 for storage and/or transmission. In one example, such collation comprises assigning an accurate GNSS location to each measured blast hole. Importantly, assigning an accurate GNSS location to each measured blast hole is valuable for accurate blast planning purposes, as blast holes are not always drilled exactly where specified by a blast plan. By apparatus 10 enabling accurate blast hole depth measurement along with accurate geographical location recording, allows accurate blast planning generally saving on costs and improving efficiency and efficacy of blasting.

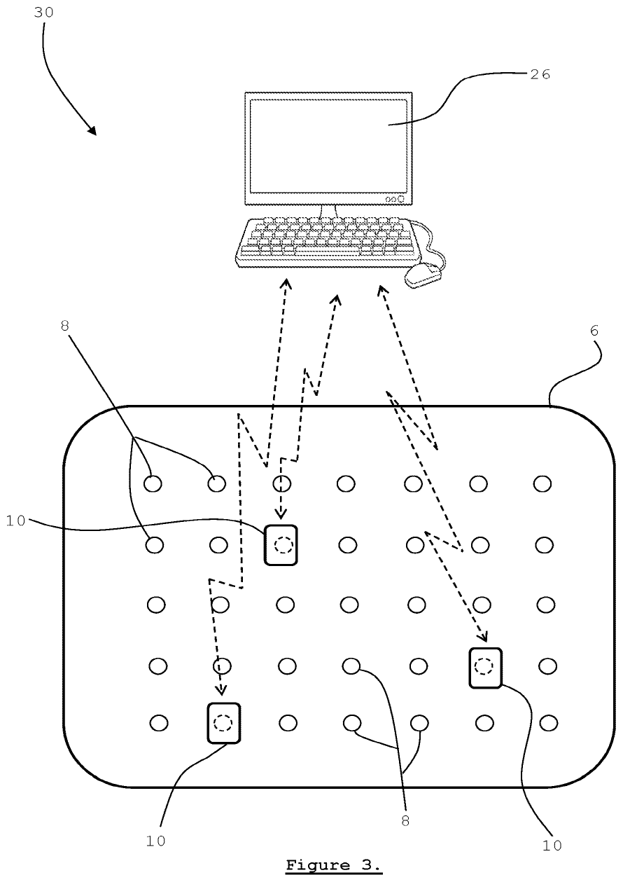

Typically, the processor 22 includes a non-transitory memory 28 wherein the geographic positional, volumetric and/or distance data is storable. The apparatus 10 also typically includes a transmitter 24 whereby the processor 22 is able to transmit the geographic positional, volumetric and/or distance data to a remote computer system 26, which is configured to log the data as part of a blast plan (described in more detail below with reference to FIG. 3).

In one example, the apparatus 10 includes a display (not shown) whereby the geographic positional, volumetric and/or distance data is displayable to a user. Typically, the display comprises an electronic ink (e-ink) display having high visibility and contrast, a wide viewing angle and low power requirements.

Similarly, the apparatus 10 generally includes energizing means (not shown) that are configured to provide electrical energy to the LiDAR sensor, GNSS module and processor. Such energizing means may include electrochemical cell(s), such as a rechargeable battery, photovoltaic cells, etc.

One embodiment sees apparatus 10 as a hand-held device whereby a person is able to walk between blast holes to capture distance and geographical data. In a further example, the apparatus 10 may be automated and includes self-propelled locomotion to move between blast holes. For example, apparatus 10 may include self-propelled locomotion comprising an aerial drone configuration able to fly over blast holes 8 to accurately measure depth and geographical position and to transmit such data to the remote computer system 26.

In another example, the apparatus 10 is mounted to an explosive loading or charging truck (automated or human operated) operatively moving between blast holes for charging the blast holes with explosives. Examples of such trucks are well-known in the art, e.g., smart charging trucks, and will not be described in any detail herein. The apparatus 10 may also be configured to automatically move over a pre-configured area to detect where blast holes are and to record such blast hole geographic positions and depths.

With reference now to FIG. 3 of the accompanying drawings, there is shown an associated blast hole measurement and logging system 30. System 30 generally comprises at least one blast hole measurement and logging apparatus 10 having housing 12 configured to operatively house the solid-state LiDAR sensor 14 for compiling the volumetric data, the a GNSS module 20 configured to provide geographic positional data, and processor 22 configured to receive the geographic positional and volumetric data from the GNSS module 20 and LiDAR sensor 14, respectively, to calculate the distance data based on the volumetric data, and to collate the distance data with the geographic positional data. Apparatus 10 further includes a transmitter 24 whereby the processor is able to transmit the collated distance and geographic positional data to the remote computer system 26, which is configured to receive the transmitted collated distance and geographic positional data and to log the data as part of a blast hole plan.

Typically, the system 30 includes a plurality of blast hole measurement and logging apparatuses 10. For example, multiple users may each have an apparatus 10, as described herein, in order to measure and map drilled blast holes accurately. In a preferred embodiment, each apparatus 10 is automated and includes self-propelled locomotion to move between blast holes 8, such as a plurality of automated aerial drones, which is able to fly over a bench or ore body 6 to accurately measure and map blast holes 8. As previously mentioned, such a plurality of automated drones may be configured to automatically search for drilled blast holes to log their geographical positions along with measured depths.

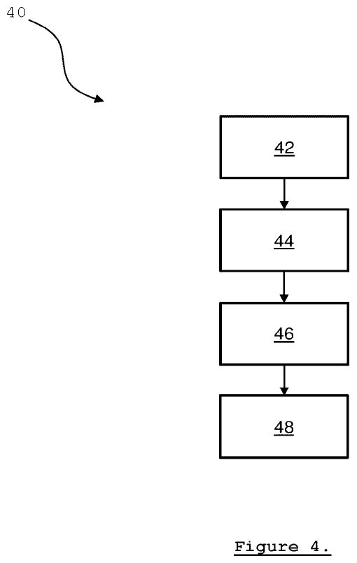

Referring now to FIG. 4 of the accompanying drawings, there is shown a flow diagram with blocks or steps representative of a method 40 for blast hole measurement and logging. The method 40 generally comprises: step 42, providing blast hole measurement and logging apparatus 10, as described herein; step 44, measuring and compiling the volumetric data for a plurality of blast holes 8; step 46, the data subsequently collated with respective geographic positional data for each blast hole; and step 48, logging the distance and geographic positional data as part of a blast hole plan.

In one example, the method 40 includes the step of calculating the distance data based on the volumetric data via point cloud algorithms configured to determine a maximum depth and/or maximum average depth of the blast hole. In one example, the maximum average depth of the blast hole is calculated via factoring for average depth against a width of the blast hole following analysis of the volumetric data. Alternatively, or additionally, the maximum depth of the blast hole is calculated via analysis of the volumetric data to determine furthest measured distance.

Optional embodiments of the present disclosure may also be said to broadly consist in the parts, elements and features referred to or indicated herein, individually or collectively, in any or all combinations of two or more of the parts, elements or features, and wherein specific integers are mentioned herein, which have known equivalents in the art to which the present disclosure relates, such known equivalents are deemed to be incorporated herein as if individually set forth. In the example embodiments, well-known processes, well-known device structures, and well-known technologies are not described in detail, as such will be readily understood by the skilled addressee.

The use of the terms “a”, “an”, “said”, “the”, and/or similar referents in the context of describing various embodiments (especially in the context of the claimed subject matter) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. As used herein, the term “and/or” includes any and all combinations of one or more of the associated listed items. No language in the specification should be construed as indicating any non-claimed subject matter as essential to the practice of the claimed subject matter.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Note that reference to “one example” or “an example” of the present disclosure, or similar exemplary language (e.g., “such as”) herein, is not made in an exclusive sense. Various substantially and specifically practical and useful exemplary embodiments of the claimed subject matter are described herein, textually and/or graphically, for carrying out the claimed subject matter.

Accordingly, one example may exemplify certain aspects of the present disclosure, while other aspects are exemplified in a different example. These examples are intended to assist the skilled person in performing the present disclosure and are not intended to limit the overall scope of the present disclosure in any way unless the context clearly indicates otherwise. Variations (e.g., modifications and/or enhancements) of one or more embodiments described herein might become apparent to those of ordinary skill in the art upon reading this application. It is expected that skilled artisans will employ such variations as appropriate, and it is expected that the claimed subject matter will be practiced other than as specifically described herein.

Any method steps, processes, and operations described herein are not to be construed as necessarily requiring their performance in the particular order discussed or illustrated, unless specifically identified as an order of performance. It is also to be understood that additional or alternative steps may be employed.

What is claimed is:

1. A blast hole measurement and logging apparatus comprising:
a housing configured to operatively house:
a solid-state light detection and ranging (“LiDAR”) sensor array configured to transmit and steer pulses of light into a blast hole by shifting a phase of the pulses through the array to compile volumetric data of the sensor's field-of-view; and
a processor configured to receive the volumetric data from the LiDAR sensor array, the volumetric data indicative of an internal volume of the blast hole useable in calculating an explosive charge according to a blast plan, and to extract intensity return data from the volumetric data, the intensity return data indicative of a surface reflectance of the blast hole which facilitates the processor in detection of water within said blast hole, the processor further configured to store and/or transmit the volumetric data.

2. The apparatus of claim 1, wherein the LiDAR sensor array includes one or more of an optical phased array configured to transmit and steer pulses of light, a microelectromechanical systems (“MEMS”) mirror array configured to transmit and steer pulses of light, and a flash LiDAR arrangement having a three-dimensional focal plane array configured to transmit and steer pulses of light.

3. The apparatus of claim 1, further comprising a thermal imaging camera arranged in signal communication with the processor for capturing a temperature profile of the blast hole.

4. The apparatus of claim 3, wherein the processor is configured to compile the temperature profile of the blast hole with the volumetric data to improve the volumetric data indicative of the internal volume of the blast hole.

5. The apparatus of claim 4, wherein the processor includes an inertial measurement unit to facilitate the processor in calculating an orientation of the blast hole.

6. The apparatus of claim 1, wherein the processor is configured to perform:
intensity correction on the intensity return data, wherein adjustment is made to intensity values to reduce or eliminate variation caused by one or more effective parameters such as range, angle of incidence
intensity normalization wherein intensity data is normalized through scaling to adjust contrast and/or a shift to adjust “brightness” to improve matching with a neighboring data point; and/or
radiometric correction and calibration wherein intensity values are first evaluated on targets with known reflectance, resulting in the determination of calibration constants for the sensor, the calibration constants are then applied to future data that are collected with the sensor to account for any deviations.

7. The apparatus of claim 1, wherein the processor is configured to calculate distance data based on one or more of a maximum depth and a maximum average depth of the blast hole.

8. The apparatus of claim 1, wherein the processor is configured to calculate a maximum average depth of the blast hole based on an average depth against a width of the blast hole according to the volumetric data.

9. The apparatus of claim 1, wherein the processor is configured to calculate the maximum depth of the blast hole based on a furthest measured distance according to the volumetric data.

10. The apparatus of claim 1, wherein the volumetric data is indicative of a lip, edge or start of the blast hole to allow the distance data to be calculated irrespective of a position of the LiDAR sensor above the blast hole.

11. The apparatus of claim 1, further comprising a GNSS module configured to provide geographic positional data for each instance when the volumetric data is compiled, the processor configured to collate the geographic positional date from the GNSS module with one or more of the volumetric data and distance data for one or more of storage and transmission.

12. The apparatus of claim 11, further comprising a transmitter, the processor able to transmit one or more of the volumetric data, the collated distance data, and the geographic positional data to a remote computer system configured to log the one or more of the volumetric data, the collated distance data, and the geographic positional data.

13. The apparatus of claim 14, further comprising a display whereby the one or more of the volumetric data, the collated distance data, and the geographic positional data are displayable to a user.

14. The apparatus of claim 1, wherein the housing comprises a ruggedized housing to protect housed components against one or more of shock, vibration, and the ingress of dust and fluid, the housing being shaped and dimensioned to be man-portable.

15. The apparatus of claim 1, wherein the apparatus is automated and includes self-propelled locomotion to move between blast holes.

16. The apparatus of claim 15, wherein the self-propelled locomotion comprises one or more of an aerial drone configuration and explosive loading or charging truck operatively moving between blast holes for charging the blast holes with explosives, wherein the self-propelled locomotion is automated or human operated.

17. The apparatus of claim 16, wherein the charging truck includes a GNSS module configured to provide geographic positional data to the processor.

18. The apparatus of claim 1, further comprising an automated or motorized dipping cord reel configured to operatively lower a dipping cord into the blast hole, the processor configured to measure a length of dispensed cord to determine a depth of the blast hole.

19. A blast hole measurement and logging system, comprising:
the apparatus of claim 1; and
a remote computer system configured to receive one or more of the volumetric data, collated distance data, geographic positional data and to log the one or more of the volumetric data, the collated distance data, and the geographic positional data as part of a blast plan.

20. A method for blast hole measurement and logging, said method comprising the steps of: providing the apparatus of claim 1;
measuring and compiling the volumetric data for a plurality of blast holes, the volumetric data subsequently collated with respective geographic positional data for each blast hole; and
logging the distance and geographic positional data as part of a blast plan.
